(19) United States
(12) Patent Application Publication
(10) Pub. No.: US 2013/0188410 A1
(43) Pub. Date: Jul. 25, 2013

(54) METHOD AND APPARATUS FOR TESTING ONE TIME PROGRAMMABLE (OTP) ARRAYS

(71) Applicants: Gregory A. Uvieghara, San Diego, CA (US); Amer Christophe G. Cassier, San Diego, CA (US); Anil C. Kota, San Diego, CA (US)

(72) Inventors: Gregory A. Uvieghara, San Diego, CA (US); Amer Christophe G. Cassier, San Diego, CA (US); Anil C. Kota, San Diego, CA (US)

(73) Assignee: QUALCOMM Incorporated, San Diego, CA (US)

(21) Appl. No.: 13/420,832

(22) Filed: Mar. 15, 2012

Related U.S. Application Data
(60) Provisional application No. 61/588,753, filed on Jan. 20, 2012.

(51) Int. Cl. G11C 29/00; G11C 17/00

(52) U.S. Cl. 365/94; 365/201

(57) ABSTRACT

An array of one time programmable (OTP) devices includes a first set of pre-configurable memory devices appended to one or more columns of me array and a second set of pre-configurable memory devices appended to one or more rows of the array. The pre-configurable memory devices may be additional OTP devices or read only memory (ROM) devices that can be configured to store a predetermined test pattern for the array. Rows, columns and functionalities of the array can be tested based on the stored test pattern. OTP devices in the array may then be programmed after successful testing based on the test pattern stored.

### CROSS REFERENCE TO RELATED APPLICATION

The present application claims the benefit of U.S. Provisional Patent Application No. 61/588,753 to Uvieghara et al., filed on Jan. 20, 2012.

### TECHNICAL FIELD

The present disclosure relates generally to one-time programmable (OTP) storage elements. More specifically, the present disclosure relates to testing arrays of OTP storage elements.

### BACKGROUND

Detection of manufacturing faults in storage elements generally involves electrical tests to store and retrieve data from these elements. Storage devices that include one-time programmable (OTP) storage elements are meant to be programmed by an end user after production tests, when they have already been incorporated in a system or device. In OTP storage elements, the programmed data is not erasable or reprogrammable. Rather OTP programming events are an irreversible destructive process. Because certain fields of OTP storage elements must remain un-programmed and dedicated for programming by a user, it has been difficult or virtually impossible to fully test one-time programmable arrays during production testing. Leaving portions of OTP storage devices untested has resulted, in an increased risk of test escapes.

An OTP array is programmed in order to test portions of read, paths such as bitlines and sense-amplifiers. However, programming the OTP elements involves relatively high voltages and currents that may cause side effects including the creation of faults by damaging program paths and read paths. The read paths cannot be independently tested if there are defects in the program controller or program logic. Present testing techniques do not provide a method to test the read paths independently without programming the OTP array.

### SUMMARY

One aspect of the present disclosure includes a method of testing an array of one-time programmable (OTP) devices. The method includes programming a first portion of a row of non-volatile memory (NVM) devices with test data and programming a first portion of a column of NVM devices with test data. The method also includes testing the row and column based on the programming of the first portions of the row and column. After a successful test, a remainder of the column and row are programmed with actual data.

Another aspect of the present disclosure includes an OTP apparatus. The OTP apparatus has an array of OTP devices arranged in rows and columns. A first set of pre-programmed ROM devices is appended to at least one column of the array. A second set of pre-programmed ROM devices is appended to at least one row of the array. The pre-programmed ROM devices store a predetermined test pattern for the array.

Another aspect of the present disclosure includes an apparatus for testing an array of OTP devices. The apparatus includes means for programming a first portion of a row of non-volatile memory (NVM) devices with test data and means for programming a first portion of a column of NVM devices with test data. The apparatus also includes means for testing the row and column based on the programming of the first portions of the row and column and means for programming a remainder of the column and row with actual data, after a successful test.

This has outlined, rather broadly, the features and technical advantages of the present disclosure in order that the detailed description that follows may be better understood. Additional features and advantages of the disclosure will be described, below. It should, be appreciated by those skilled, in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identity correspondingly throughout.

FIG. 1 is a schematic diagram conceptually illustrating a configuration of a one time programmable (OTP) array according to one aspect of the present disclosure.

FIG. 2 is a schematic diagram conceptually illustrating a configuration of an OTP array according to another aspect of the present disclosure.

FIG. 3 is a schematic diagram conceptually illustrating a configuration of an OTP array according to still another aspect of the present disclosure.

FIG. 4 is a schematic diagram conceptually illustrating a configuration of an OTP array according to yet another aspect of the present disclosure.

FIG. 5 is a process flow diagram illustrating a method of testing an array of OTP devices according to an aspect of the present disclosure.

FIG. 6 shows an exemplary wireless communication system in which a configuration of the disclosure may be advantageously employed,

FIG. 7 is a block diagram illustrating a design workstation for circuit, layout, and logic design of a semiconductor component according to one aspect of the present disclosure.

### DETAILED DESCRIPTION

A first aspect of the present disclosure provides sacrificial cells to enable full testing of OTP arrays. Rows and columns are added that have sacrificial cells, which can be used for full testing of one-time programmable arrays. For this aspect, any number of sacrificial rows and sacrificial columns can be appended, to the array to ensure full testability. By writing data to the sacrificial rows and columns, testing of read functionality can be accomplished. That is, the data written to the sacrificial rows and columns is read during testing operations. Moreover, by confirming the OTP cells are properly written, the write functionality is also tested.

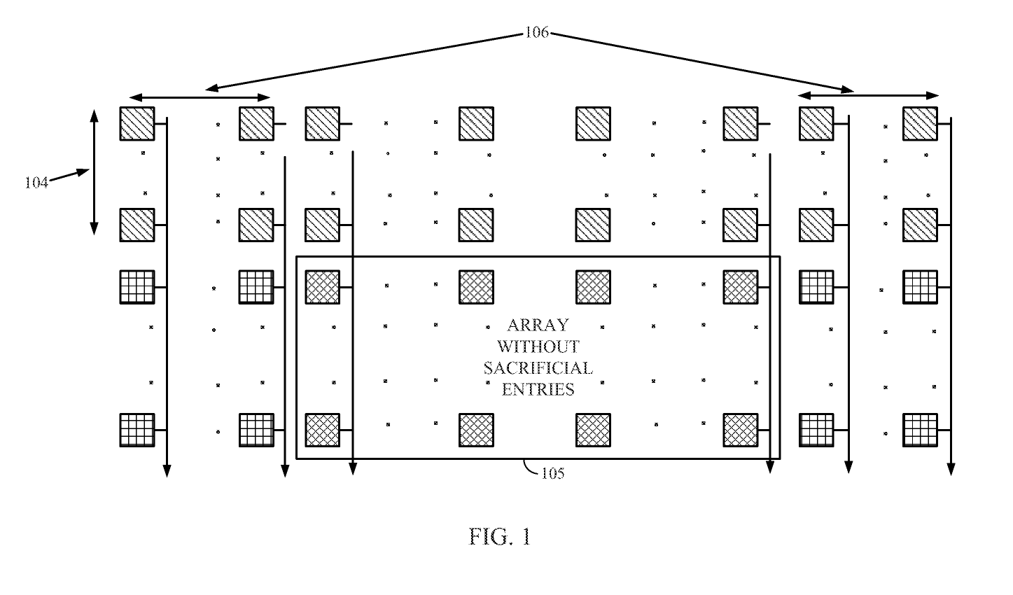

One aspect of the disclosure is described with reference to FIG. 1. One or more sacrificial rows 104 are placed above a non-sacrificial array 105. The sacrificial row(s) 104 can be placed before or after any row of the non-sacrificial array. One or more sacrificial columns 106 are placed to the left and/or right of the non-sacrificial array 105. The sacrificial column(s) 106 can be placed before or after any column of the non-sacrificial array 105.

FIG. 2 illustrates a particular implementation of the disclosure in which two sacrificial rows 204 and two sacrificial columns 206 are appended, to a non-sacrificial array 205. In this configuration, the sacrificial rows 204 and sacrificial columns 206 may be accessed directly to enable full testing of various functionalities of the non-sacrificial array. FIG. 2 shows sacrificial cells without multiplexed most significant bit (MSB) and least significant bit (LSB) columns.

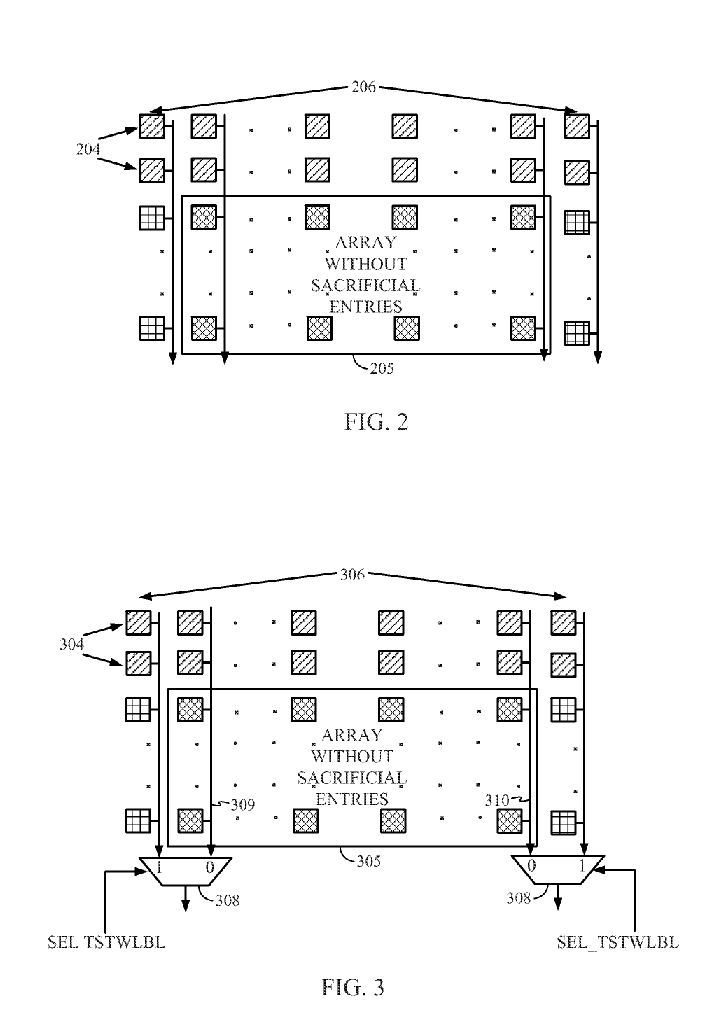

FIG. 3 illustrates another particular implementation of the disclosure in which two sacrificial rows 304 and two sacrificial columns 306 are appended to a non sacrificial array 305. This configuration also includes multiplexing circuitry 308 coupled to the sacrificial columns 306. In this configuration, sacrificial cells in the sacrificial columns 306 are multiplexed with a most significant bit (MSB) column 309 and a least significant bit (LSB) column 310 of the non-sacrificial array 305.

The multiplexing function reduces or minimizes the number of macro outputs by allowing both sacrificial columns and non-sacrificial columns to share one output through the multiplexing circuitry 308. In other words, the multiplexing circuitry 308 enables a designer to maintain the same number of outputs after introducing the sacrificial columns. The multiplexer control signals labeled “SEL TSTWLBL” in FIG. 3, select either sacrificial columns (with a value of 1) or non-sacrificial columns (with a value of 0).

Other aspects of the present disclosure provide methods for designing OTP arrays for testability. The designs include sacrificial storage element fields strategically placed and programmed with various patterns or various read/write sequences to improve/maximize test coverage. Innumerable different patterns can be programmed in sacrificial rows and sacrificial columns of an OTP array according to the present disclosure.

Programming various patterns into sacrificial rows and sacrificial columns of an OTP array enables full testing of various functionalities of the OTP array. OTP array functionalities that may be tested by such patterns include programmability of the OTP cells, bitline functionality, wordline functionality, functionality of read sense-amplifiers, data out buffers and latches, program controller functionality, functionality of the program logic for programming the OTP ceils, and/or functionality of rows and row decoders, for example.

In addition to testing the functionality of OTP arrays, the configuration of sacrificial rows and sacrificial columns can provide a way to monitor the yield and reliability of the OTP cells. The configuration also enables the test set up to be verified.

The sacrificial rows and columns can be one time programmable (OTP) cells, as described above, or alternatively can be other types of non volatile memory, such as read only memory (ROM) ceils. Read-only memory (ROM) rows and ROM columns can be added to an OTP array to provide read testability of the OTP array. The number of ROM rows and ROM columns to be appended to the array should ensure full testability. ROM cells enable testing without programming of an OTP cell. Thus, the ROM rows and columns enable testing of read functionality regardless of whether write circuitry is fully operational.

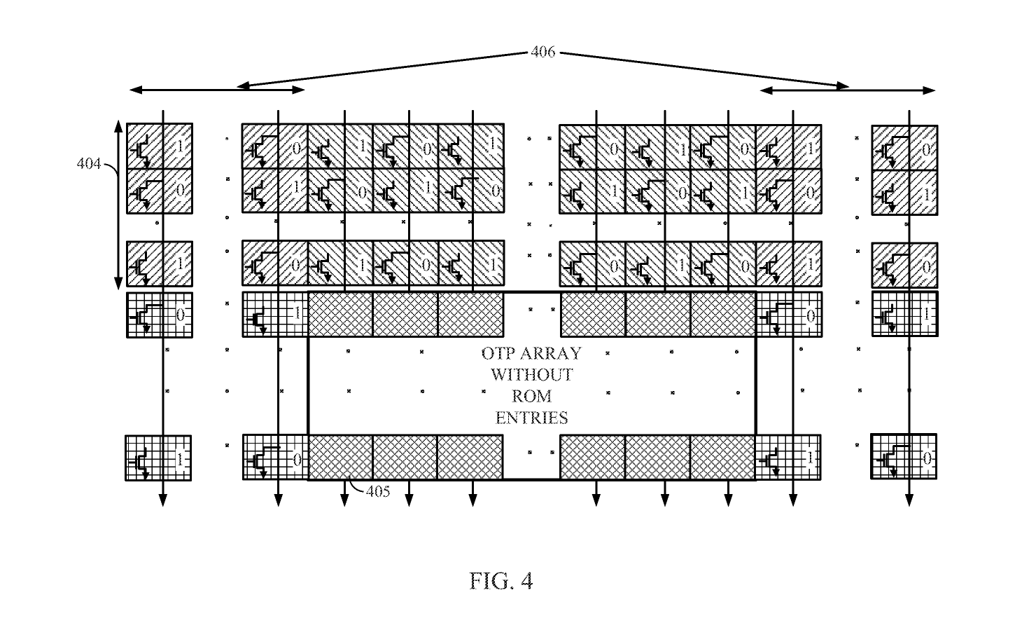

FIG. 4 shows a particular implementation of the ROM aspect of the disclosure. According to this aspect, ROM rows 404 are placed above the OTP array 405 and ROM columns 406 are placed to the left and right of the OTP array 405. However, it should be understood, that the ROM row(s) 404 can be placed before or after any row of the OTP array 405 and the ROM column(s) 406 can be placed, before or after any column of the OTP array 405 in other configurations. The ROM rows 404 and ROM columns 406 can be used to test the bitlines of the OTP array, sense-amplifiers for the READ operations, rows, row decoders, and/or data out latches/buffers, for example. This configuration can also be used for defect assessment before programming the OTP array, for example.

In one configuration, according to an aspect of the present disclosure, the ROM rows 404 include at least two rows and the ROM columns 406 include at least two columns. A predetermined test pattern can include alternating ones and zeros, for example as seen in FIG. 4. Multiplexer circuitry may be configured for selecting between a row of the OTP array 405 and a row 404 of the ROM cells. The multiplexer circuitry (not shown) may also be configured for selecting between a column of the OTP array 405 and a column 406 of the ROM device, for example.

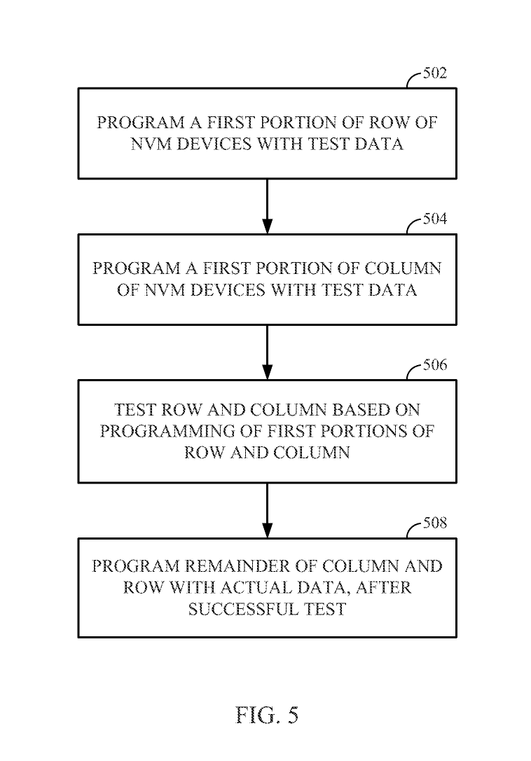

A method of testing an array of one-time programmable (OTP) devices according to an aspect of the present disclosure is described with reference to FIG. 5. The method programs a first portion of a row of non volatile memory (NVM) devices (which can include OTP elements or ROM elements) with test data in block 502 and programs a first portion of a column of non-volatile memory devices with test data in block 504. In block 506, the method tests the row and column based on the programming of the first portions of the row and column. In block 508, the method includes programming a remainder of the column and row with actual data, after a successful test.

An apparatus for testing an array of one-time programmable (OTP) devices according to one aspect of the present disclosure includes means for programming a first portion of a row of NVM devices with test data and means for programming a first portion of a column of NVM devices with test data. The apparatus also includes means for testing the row and column based on the programming of the first portions of the row and column and means for programming a remainder of the column and row with actual data, after a successful test.

The programming means may be the bitlines, rows, row decoders, program controller, and/or programming logic. The means for testing a first portion of a row may be sacrificial columns 106, 206, 306, or ROM columns 406, and the means for testing a first portion of a column may be sacrificial rows 104, 204, 304, or ROM rows 404, for example. The means for programming the remainder of the column and row with actual data may include the non-sacrificial rows and columns of the OTP array 105, 205, 305, 405, for example. Although specific means have been set forth, it will be appreciated by those skilled in the art that not all of the disclosed means are required to practice the disclosed configurations. Moreover, certain well known means have not been described, to maintain focus on the disclosure.

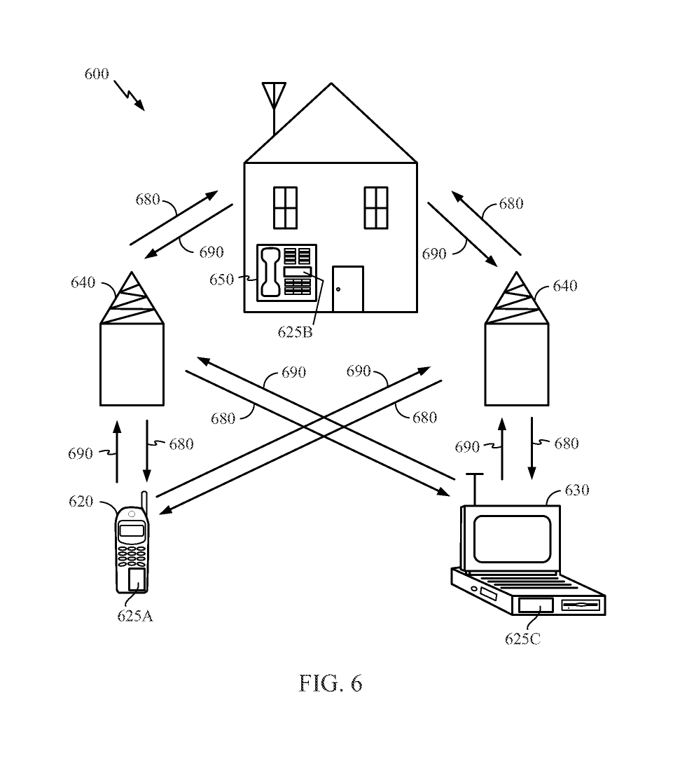

FIG. 6 shows an exemplary wireless communication system 600 in which a configuration of the disclosed OTP array may be advantageously employed. For purposes of illustration, FIG. 6 shows three remote units 620, 630, and 650 and two base stations 640. It will be recognized that wireless communication systems may have many more remote units and base stations. Remote units 620, 630, and 650 include the OTP array 625A, 625B, and 625C, respectively. FIG. 6 shows forward link signals 680 from the base stations 640 and the remote units 620, 630, and 650 and reverse link signals 690 from the remote units 620, 630, and 650 to base stations 640.

In FIG. 6, the remote unit 620 is shown as a mobile telephone, remote unit 630 is shown as a portable computer, and remote unit 650 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 6 illustrates remote units, which may employ OTP array according to the teachings of the disclosure, the disclosure is not limited to these exemplary illustrated units. For instance, timing locking circuitry according to configurations of the present disclosure may be suitably employed in any device.

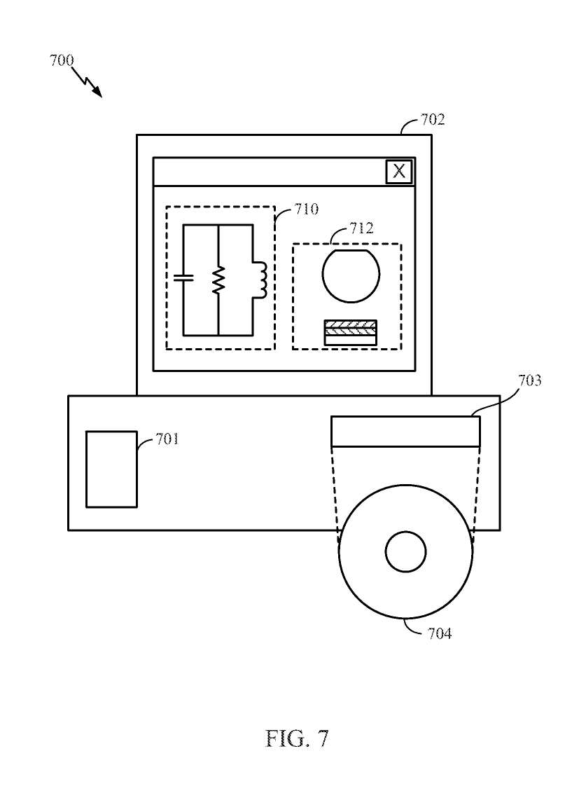

FIG. 7 is a block diagram illustrating a design workstation used for circuit, layout, and logic design of a semiconductor component, such as the OTP array disclosed above. A design workstation 700 includes a hard, disk 701 containing operating system software, support files, and design software such as Cadence or OrCAD. The design workstation 700 also includes a display 702 to facilitate design of a circuit 710 or a semiconductor component 712 such as the OTP array. A storage medium 704 is provided for tangibly storing the circuit design 710 or the semiconductor component 712. The circuit design 710 or the semiconductor component 712 may be stored on the storage medium 704 in a file format such as GDSII or GERBER. The storage medium 704 may be a CD-ROM, DVD, hard disk, flash memory, or other appropriate device. Furthermore, the design workstation 700 includes a drive apparatus 703 for accepting input from or writing output to the storage medium 704.

Data recorded on the storage medium 704 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 704 facilitates the design of the circuit design 710 or the semiconductor component 712 by decreasing the number of processes for designing semiconductor wafers.

Although specific circuitry has been set forth, it will be appreciated, by those skilled in the art that not all of the disclosed circuitry is required to practice the disclosed configurations. Moreover, certain well known circuits have not been described, to maintain focus on the disclosure.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored, in a memory and executed by a processor unit. Memory may be implemented within the processor unit or external to the processor unit. As used herein the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular configurations of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A method of testing an array of one-time programmable (OTP) devices, comprising:
programming a first portion of a row of non-volatile memory (NVM) devices with test data;
programming a first portion of a column of NVM devices with test data;
testing the row and column based on the programming of the first portions of the row and column; and
programming a remainder of the column and row with actual data, after a successful test.

2. The method, of claim 1, in which the testing comprises testing write functionality of the array.

3. The method of claim 1, further comprising testing read functionality of the array.

4. The method of claim 1, in which the first portion of the row comprises two OTP devices.

5. The method of claim 1 further comprising: integrating the OTP devices into at least one of a mobile phone, a set top box, a music player, a video player, an entertainment unit, a navigation device, a computer, a hand-held personal communication systems (PCS) unit, a portable data unit, and a fixed location data unit.

6. An apparatus comprising:
an array of one-time programmable (OTP) devices arranged in a plurality of rows and columns;
a first plurality of pre-programmed ROM devices appended to at least one column of the array; and
a second plurality of pre-programmed ROM devices appended to at least one row of the array, the pre-programmed ROM devices storing a predetermined test pattern for the array.

7. The apparatus of claim 6, in which the pre-programmed ROM devices include at least two rows and at least two columns and the predetermined test pattern includes alternating ones and zeros.

8. The apparatus of claim 6, in which the pre-programmed ROM devices are configured for testing the array of OTP devices.

9. The apparatus of claim 6, in which the pre-programmed ROM devices are configured for testing write functionality of the array.

10. The apparatus of claim 6, in which the pre-programmed ROM devices are configured for testing read functionality of the array.

11. The apparatus of claim 6, in which the first plurality of pre-programmed. ROM devices comprises two first ROM devices appended to a first column of the array, and the second plurality of pre-programmed ROM devices comprises two second ROM devices appended to a first row of the array.

12. The apparatus of claim 6, integrated in at least one of a mobile phone, a set top box, a music player, a video player, an entertainment unit, a navigation device, a computer, a hand-held personal communication systems (PCS) unit, a portable data unit, and a fixed location data unit.

13. An apparatus for testing an array of one-time programmable (OTP) devices, comprising:
means for programming a first portion of a row non-volatile memory (NVM) devices with test data;
means for programming a first portion of a column NVM devices with test data;
means for testing the row and column based, on the programming of the first portions of the row and column; and
means for programming a remainder of the column and row with actual data, after a successful test.

14. The apparatus of claim 13, in which the means for testing the row and column include means for testing write functionality of the array.

15. The apparatus of claim 13, in which the means for testing the row and column include means for testing read functionality of the array.

16. The apparatus of claim 13, integrated in at least one of a mobile phone, a set top box, a music player, a video player, an entertainment unit, a navigation device, a computer, a hand-held personal communication systems (PCS) unit, a portable data unit, and a fixed location data unit.

17. A method of testing an array of one-time programmable (OTP) devices, comprising steps of:
programming a first portion of a row of non-volatile memory (NVM) devices with test data;
programming a first portion of a column of NVM devices with test data;
testing the row and column based on the programming of the first portions of the row and column; and
programming a remainder of the column and row with actual data, after a successful test.

18. The method, of claim 17, in which the testing comprises a step of testing write functionality of the array.

19. The method of claim 17, further comprising a step of testing read functionality of the array.

20. The method of claim 17 further comprising a step of: integrating the OTP devices into at least one of a mobile phone, a set top box, a music player, a video player, an entertainment unit, a navigation device, a computer, a hand-held personal communication systems (PCS) unit, a portable data unit, and a fixed location data unit.
